(19) United States
(12) Patent Application Publication
(10) Pub. No.: US 2019/0064574 A1
(43) Pub. Date: Feb. 28, 2019

(54) DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jun CHEN, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 15/576,526

(22) PCT Filed: Nov. 6, 2017
(86) PCT No.: PCT/CN2017/109522

§ 371 Date: Nov. 22, 2017

(30) Foreign Application Priority Data
Aug. 30, 2017 (CN) 201710762564.2

(51) Int. Cl. G02F 1/1345; G02F 1/1335; G02F 1/1333; H01L 27/32; H01L 51/00

(52) U.S. Cl. CPC G02F 1/13454; G02F 1/133514; G02F 1/133305; H01L 27/3244; H01L 2227/326; H01L 51/003; G02F 2001/133302; H01L 2251/5338; H01L 51/0097

(57) ABSTRACT

A display panel has a first substrate, an array substrate, and a light-emitting displaying layer. The array substrate has a base layer and a plastic substrate layer disposed on the base layer and configured to dispose pixel units and a driver chip. The array substrate has a displaying region corresponding to the first substrate and a driving region disposed on a side of the displaying region. The base layer of the array substrate of the displaying region is a glass substrate, and the base layer of the array substrate of the driving region is a reinforcing plate.

### FIELD OF THE INVENTION

The present invention relates to the field of display technologies, especially to a display panel.

### BACKGROUND OF THE INVENTION

Displaying technologies are constantly developing and user requirements to displaying devices are increasing. Therefore, displaying devices in variety of electrical apparatuses tend to have narrower edge frames and to be thinner in thickness.

With edge frames of display panels of the displaying devices becoming narrower and the thicknesses of the display panels becoming thinner, reliability of the display panels of the displaying devices decreases accordingly with issues such as cracks and damage.

With respect to a disposing area of a driver chip of the display panel, because the driver chip of the display panel is generally disposed on a corresponding glass substrate by a chip on glass (COG) method and the glass substrate corresponding to the driver chip is a single layer, the glass substrate corresponding to the driver chip easily suffers from cracks or damage when the display panel is moved, transported, or undergoes reliability testing.

Therefore, it is necessary to provide a display panel for solving the issues of conventional technologies.

### SUMMARY OF THE INVENTION

The present invention provides a display panel able to prevent a glass substrate from crack and damages. The present invention solves easily cracking and damaging issues of glass substrates happening during movement, transportation or reliability tests of the conventional display panels.

An embodiment of the present invention provides a display panel comprising:

a first substrate, an array substrate, and a light-emitting displaying layer disposed between the first substrate and the array substrate;

the array substrate comprising a base layer and a plastic substrate layer disposed on the base layer and configured to dispose pixel units and a driver chip;

the array substrate comprising a displaying region corresponding to the first substrate, and a driving region disposed on a side of the displaying region; wherein the pixel units are disposed on the plastic substrate layer of the displaying region, and the driver chip is disposed on the plastic substrate layer of the driving region;

the base layer of the array substrate of the displaying region being a glass substrate, and the base layer of the array substrate of the driving region being a reinforcing plate;

a projection of the reinforcing plate on a plane on which the first substrate lies partially coinciding with the first substrate;

a thickness of the reinforcing plate substantially equal to a thickness of the glass substrate.

In the display panel of the present invention, the reinforcing plate is disposed by steps as follows:

coating the plastic substrate layer on the glass substrate;

lifting off the glass substrate corresponding to the driving region by a laser lift-off technology; and

disposing the reinforcing plate on an outside of the plastic substrate layer of the driving region.

In the display panel of the present invention, when the display panel is a liquid crystal display panel, the first substrate is a color filter substrate.

In the display panel of the present invention, when the display panel is an organic light-emitting diode (OLED) display panel, the first substrate is a packaged glass substrate.

The embodiment of the present invention provides a display panel comprising:

a first substrate, an array substrate, and a light-emitting displaying layer disposed between the first substrate and the array substrate;

the array substrate comprising a base layer and a plastic substrate layer disposed on the base layer and configured to dispose pixel units and a driver chip;

the array substrate comprising a displaying region corresponding to the first substrate and a driving region disposed on a side of the displaying region; wherein the pixel units are disposed on the plastic substrate layer of the displaying region, and the driver chip is disposed on the plastic substrate layer of the driving region; and

the base layer of the array substrate of the displaying region being a glass substrate, and the base layer of the array substrate of the driving region being a reinforcing plate.

In the display panel of the present invention, a projection of the reinforcing plate on a plane on which the first substrate lies partially coincides with the first substrate.

In the display panel of the present invention, a thickness of the reinforcing plate is substantially equal to a thickness of the glass substrate.

In the display panel of the present invention, the reinforcing plate is disposed by steps as follows:

coating the plastic substrate layer on the glass substrate;

lifting off the glass substrate corresponding to the driving region by a laser lift-off technology; and

disposing the reinforcing plate on an outside of the plastic substrate layer of the driving region.

In the display panel of the present invention, when the display panel is a liquid crystal display panel, the first substrate is a color filter substrate.

In the display panel of the present invention, when the display panel is an OLED display panel, the first substrate is a packaged glass substrate.

The embodiment of the present invention further provides a display panel comprising:

a first substrate, an array substrate, and a light-emitting displaying layer disposed between the first substrate and the array substrate;

the array substrate comprising a pixel unit substrate configured to dispose pixel units and corresponding to the first substrate and a driver chip substrate disposed on a side of the pixel unit substrate and configured to dispose a driver chip; and

the pixel unit substrate being glass substrate, and the driver chip substrate comprising a reinforcing plate and a plastic substrate layer disposed on the reinforcing plate.

In the display panel of the present invention, a projection of the plastic substrate layer on a plane on which the reinforcing plate lies covers the reinforcing plate.

In the display panel of the present invention, a projection of the plastic substrate layer on a plane on which the first substrate lies partially coincides with the first substrate.

In the display panel of the present invention, a thickness of the reinforcing plate is substantially equal to a thickness of the glass substrate.

In the display panel of the present invention, when the display panel is a liquid crystal display panel, the first substrate is a color filter substrate.

In the display panel of the present invention, when the display panel is an OLED display panel, the first substrate is a packaged glass substrate.

The display panel of the present invention disposed with the reinforcing plate allows the array substrate corresponding to the driver chip to acquire better support and protection such that the glass substrate of the display panel is prevented from cracks and damages. The issues that corresponding glass substrates are easily cracked and damaged during movement, transportation or reliability tests of the conventional display panels are solved.

### DESCRIPTION OF THE DRAWINGS

To more clearly describe technological solutions of embodiments of the present invention, accompanied figures necessarily for describing the embodiments will be briefly introduced as follows. Apparently, the following described figures are merely some embodiments of the present invention, and a person of ordinary skill in the art may obtain other figures based on these figures without creative efforts.

FIG. 1 is a top view of a first preferred embodiment of a display panel of the present invention;

FIG. 2 is a side view of the first preferred embodiment of the display panel of the present invention;

FIG. 3 is a side view of a variant of the first preferred embodiment of the display panel of the present invention;

FIG. 4 is a side view of another variant of the first preferred embodiment of the display panel of the present invention;

FIG. 5 is a side view of another variant of the first preferred embodiment of the display panel of the present invention;

FIG. 6 is a top view of a second preferred embodiment of a display panel of the present invention;

FIG. 7 is a side view of the second preferred embodiment of the display panel of the present invention; and

FIG. 8 is a side view of a variant of the second preferred embodiment of the display panel of the present invention.

### DETAILED DESCRIPTION OF THE PREFERRED EMBODIMENTS

Technology solutions of the embodiments of the present invention will be described clearly and completely with accompanied figures of the embodiments of the present invention as follows. Apparently, the described embodiments are part of the embodiments of the present invention instead of all embodiments. Based on embodiments of the present invention, all other embodiments that may be acquired by a person of ordinary skill in the art without creative efforts are within the extent of the scope of the present invention.

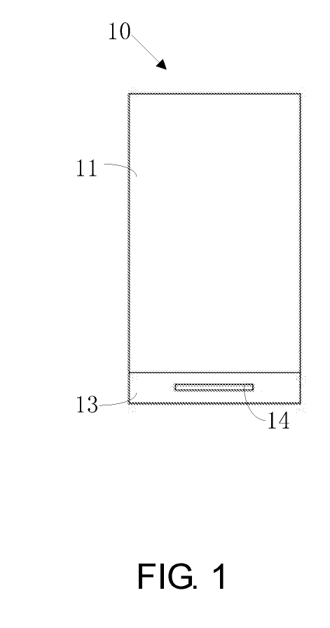

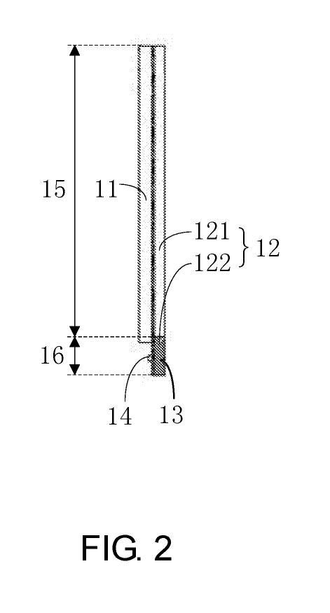

With reference to FIGS. 1 and 2, FIG. 1 is a top view of a first preferred embodiment of a display panel of the present invention. FIG. 2 is a side view of the first preferred embodiment of the display panel of the present invention. The display panel 10 of the preferred embodiment comprises a first substrate 11, an array substrate, and a light-emitting displaying layer (not shown in figures) disposed between the first substrate 11 and the array substrate.

When the display panel 10 is a liquid crystal display panel, the first substrate 11 is a color filter substrate, and the light-emitting displaying layer is a liquid crystal layer. When display panel 10 is an organic light-emitting diode (OLED) display panel, the first substrate 11 is a packaged glass substrate, and the light-emitting displaying layer is an OLED light-emitting layer.

The array substrate comprises a base layer 12 and a plastic substrate layer 13 disposed on the base layer 12 and configured to dispose pixel units and a driver chip 14. The array substrate comprises a displaying region 15 corresponding to the first substrate 11, and a driving region 16 disposed on a side of the displaying region 15. The pixel units are disposed on the plastic substrate layer 13 of the displaying region 15, and the driver chip 14 is disposed on the plastic substrate layer 13 of the driving region 16.

The base layer 12 of the array substrate of the displaying region 15 is a glass substrate 121. The base layer 12 of the array substrate of the driving region 16 is a reinforcing plate 122. reinforcing plate 122 is preferably a metal plate, a rubber plate or a plastic plate.

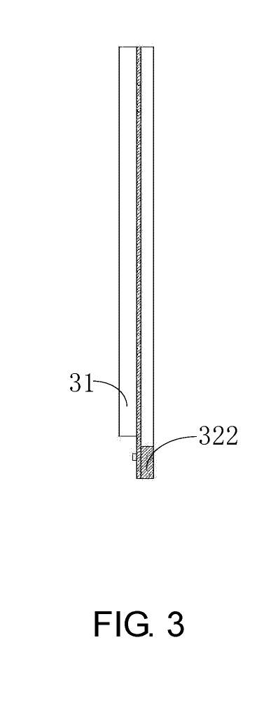

In the preferred embodiment, a projection of the reinforcing plate 122 on a plane on which the first substrate 11 lies partially coincides with the first substrate 11 such that the reinforcing plate 122 is able to provide better support and protection to the array substrate of the driving region 16. Of course, according to user requirements, the reinforcing plate 122 may be set as a reinforcing plate 322 with a projection of the reinforcing plate 322 on a plane on which the first substrate 31 lies separating from the first substrate 31 (as shown in FIG. 3).

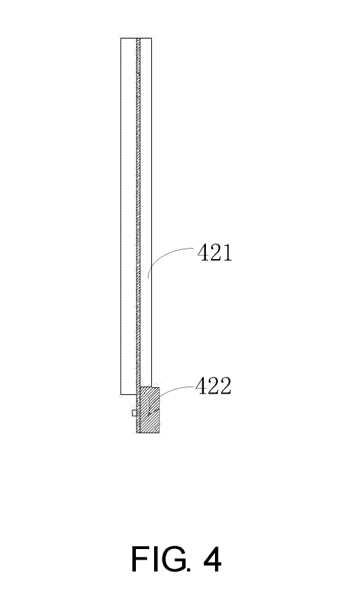

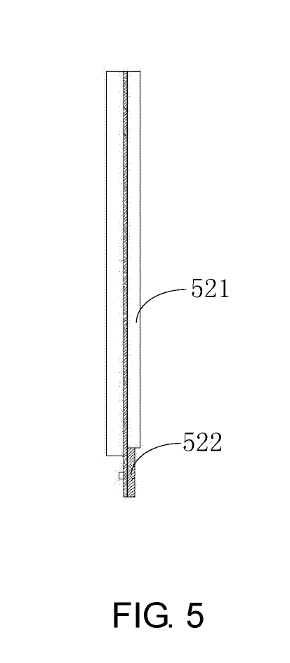

A thickness of the reinforcing plate 122 of the preferred embodiment is substantially equal to a thickness of the glass substrate 121 to facilitate installation of the array substrate. Of course, the thickness of the reinforcing plate 122 may be set according to user requirements. For example, the thickness of the reinforcing plate 422 is greater than the thickness of the glass substrate 421 (as shown in FIG. 4). Alternatively, the thickness of the reinforcing plate 522 is less than the thickness of the glass substrate 521 (as shown in FIG. 5).

When the display panel 10 of the preferred embodiment is in use, because the base layer 12 of the array substrate of the driving region 16 is changed from the glass substrate to the reinforcing plate 122 that is not cracked, the technical issue that the array substrate of the driving region 16 is easily cracked are obviated or mitigated.

Explanation about how to dispose the reinforcing plate on the array substrate of the driving region as a base layer will be described as follows.

First, a glass substrate 121 is provided. Then, a plastic substrate layer 13 is coated on the glass substrate. The plastic substrate layer 13 is at least one of polyimide (PI), polyethylene terephthalate (PET), poly(ethylene naphthalate) (PEN), polycarbonate (PC), poly(ether sulfones) (PES). The thickness of the plastic substrate layer 13 is from 10 microns to 150 microns. In a preferred embodiment, the plastic substrate layer 13 is polyimide (PI) and the thickness of the plastic substrate layer is 20 microns. Then driver circuits of thin film transistors, data lines and scan lines are manufactured on the plastic substrate layer 13 corresponding to the displaying region 15 to form pixel units. A driver chip and a corresponding driver circuit are disposed on the plastic substrate layer 13 of the driving region 16.

When the display panel 10 is a liquid crystal display panel, the color filter substrate and the array substrate are utilized continuously to implement cell-assembling operation to form light-emitting units corresponding to the pixel units. When the display panel 10 is an OLED display panel, a packaged glass substrate is utilized to implement packaging operation to the array substrate to form light-emitting units corresponding the pixel units.

Soon after, the glass substrate corresponding to the driving region 16 is lifted off by a laser lift-off (LLO) technology.

Finally, the reinforcing plate 122 is disposed on an outside of the plastic substrate layer 13 of the driving region 16 by adhesive to enhance support and protection to the plastic substrate layer 13 of the driving region 16.

The display panel of the preferred embodiment disposed with the reinforcing plate provides better support and protection to the array substrate corresponding to the driver chip such that the glass substrate of the display panel is prevented from cracks and damages.

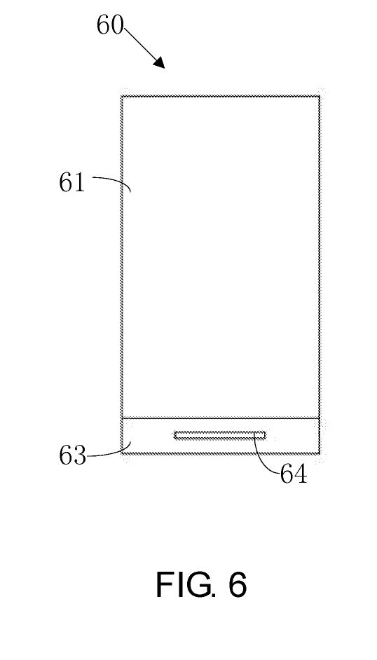

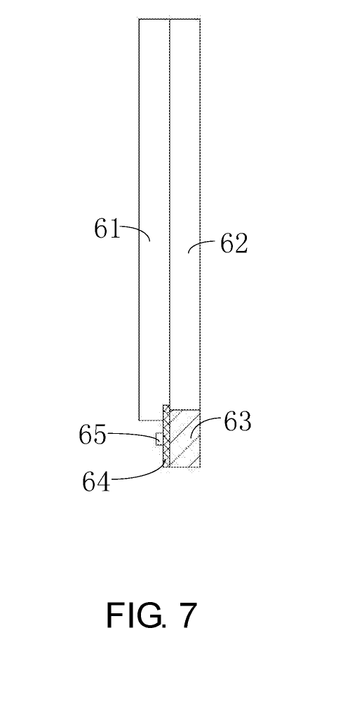

With reference to FIGS. 6 and 7, FIG. 6 is a top view of a second preferred embodiment of the display panel of the present invention. FIG. 7 is a side view of the second preferred embodiment of the display panel of the present invention. The display panel 60 of the preferred embodiment comprises a first substrate 61, an array substrate, and a light-emitting displaying layer (not shown in figures) disposed between the first substrate 61 and the array substrate.

When the display panel 60 is a liquid crystal display panel, the first substrate 61 is a color filter substrate, and the light-emitting displaying layer is a liquid crystal layer. When the display panel 60 is an OLED display panel, the first substrate 61 is a packaged glass substrate, and the light-emitting displaying layer is an OLED light-emitting layer.

The array substrate comprises a pixel unit substrate configured to dispose pixel units and corresponding to the first substrate 61 and a driver chip substrate disposed on a side of the pixel unit substrate and configured to dispose a driver chip 65.

The pixel unit substrate is a glass substrate 62, and the driver chip substrate comprises a reinforcing plate 63 and a plastic substrate layer 64 disposed on the reinforcing plate 63. Preferably, the reinforcing plate 63 is metal plate, a rubber plate or a plastic plate.

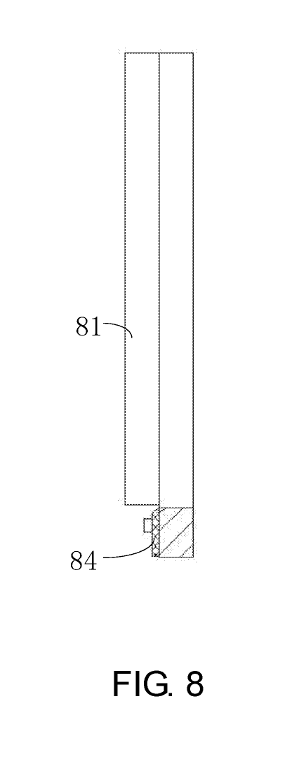

In the preferred embodiment, a projection of the plastic substrate layer 64 on a plane on which the reinforcing plate 63 lies covers the reinforcing plate 63. A projection of the plastic substrate layer 64 on a plane on which the first substrate 61 lies partially coincides with the first substrate 61 such that the reinforcing plate 63 provide better support and protection to the plastic substrate layer 64. Of course, according to user requirements, the plastic substrate layer 64 may be set to have a projection of the plastic substrate layer 84 on a plane on which the first substrate 81 lies separating from the first substrate 81 (as shown in FIG. 8).

In the preferred embodiment, a thickness of the reinforcing plate 63 is substantially equal to a thickness of the glass substrate 62 to install and dispose the array substrate. Of course, the thickness of the reinforcing plate 63 may be set according to the user's requirement. For example, the thickness of the reinforcing plate 63 is greater than a thickness of the glass substrate 62. Alternatively, the thickness of the reinforcing plate 63 is less than the thickness of the glass substrate 62.

When the display panel 60 of the preferred embodiment is used, because the plastic substrate layer 64 is disposed on the reinforcing plate 63 that is not cracked, the technical issue that the array substrate of the driving region is easily cracked are obviated or mitigated.

Based on the first preferred embodiment, the display panel of the preferred embodiment merely disposes the plastic substrate layer on a corresponding region of the driver chip and further simplifies the structure of the display panel based on ensured stable works of the array substrate on the corresponding region of the driver chip.

The display panel of the present invention disposed with the reinforcing plate allows the array substrate corresponding to the driver chip to acquire better support and protection such that the glass substrate of the display panel is prevented from cracks and damages. The issues that corresponding glass substrates are easily cracked and damaged during movement, transportation or reliability tests of the conventional display panels are solved.

Although the present invention has disclosed the preferred embodiments as above, the above preferred embodiments are not used to limit the present invention. A person of ordinary skill in the art may implements various changes and modifications without departing from the spirit and the scope of the present invention. Therefore, the protecting scope of the present invention is based on the scope of the claims.

What is claimed is:

1. A display panel, comprising:
a first substrate, an array substrate, and a light-emitting displaying layer disposed between the first substrate and the array substrate;
the array substrate comprising a base layer and a plastic substrate layer disposed on the base layer and configured to dispose pixel units and a driver chip;
the array substrate comprising a displaying region corresponding to the first substrate and a driving region disposed on a side of the displaying region; wherein the pixel units are disposed on the plastic substrate layer of the displaying region, and the driver chip is disposed on the plastic substrate layer of the driving region;
the base layer of the array substrate of the displaying region being a glass substrate, and the base layer of the array substrate of the driving region being a reinforcing plate;
a projection of the reinforcing plate on a plane on which the first substrate lies partially coinciding with the first substrate; and
a thickness of the reinforcing plate substantially equal to a thickness of the glass substrate.

2. The display panel as claimed in claim 1, wherein the reinforcing plate is disposed by steps as follows:
coating the plastic substrate layer on the glass substrate;
lifting off the glass substrate corresponding to the driving region by a laser lift-off technology; and
disposing the reinforcing plate on an outside of the plastic substrate layer of the driving region.

3. The display panel as claimed in claim 1, wherein when the display panel is a liquid crystal display panel, the first substrate is a color filter substrate.

4. The display panel as claimed in claim 1, when the display panel is an organic light-emitting diode (OLED) display panel, the first substrate is a packaged glass substrate.

5. A display panel, comprising:
a first substrate, an array substrate, and a light-emitting displaying layer disposed between the first substrate and the array substrate;
the array substrate comprising a base layer and a plastic substrate layer disposed on the base layer and configured to dispose pixel units and a driver chip;
the array substrate comprising a displaying region corresponding to the first substrate and a driving region disposed on a side of the displaying region; wherein the pixel units are disposed on the plastic substrate layer of the displaying region, and the driver chip is disposed on the plastic substrate layer of the driving region; and
the base layer of the array substrate of the displaying region being a glass substrate, and the base layer of the array substrate of the driving region being a reinforcing plate.

6. The display panel as claimed in claim 1, wherein a projection of the reinforcing plate on a plane on which the first substrate lies partially coincides with the first substrate.

7. The display panel as claimed in claim 1, wherein a thickness of the reinforcing plate is substantially equal to a thickness of the glass substrate.

8. The display panel as claimed in claim 1, wherein the reinforcing plate is disposed by steps as follows:
coating the plastic substrate layer on the glass substrate;
lifting off the glass substrate corresponding to the driving region by a laser lift-off technology; and
disposing the reinforcing plate on an outside of the plastic substrate layer of the driving region.

9. The display panel as claimed in claim 1, wherein when the display panel is a liquid crystal display panel, the first substrate is a color filter substrate.

10. The display panel as claimed in claim 1, wherein when the display panel is an OLED display panel, the first substrate is a packaged glass substrate.

11. A display panel, comprising:
a first substrate, an array substrate, and a light-emitting displaying layer disposed between the first substrate and the array substrate;
the array substrate comprising a pixel unit substrate configured to dispose pixel units and corresponding to the first substrate and a driver chip substrate disposed on a side of the pixel unit substrate and configured to dispose a driver chip; and
the pixel unit substrate being a glass substrate, and the driver chip substrate comprising a reinforcing plate and a plastic substrate layer disposed on the reinforcing plate.

12. The display panel as claimed in claim 11, wherein a projection of the plastic substrate layer on a plane on which the reinforcing plate lies covers the reinforcing plate.

13. The display panel as claimed in claim 11, wherein a projection of the plastic substrate layer on a plane on which the first substrate lies partially coincides with the first substrate.

14. The display panel as claimed in claim 11, wherein a thickness of the reinforcing plate is substantially equal to a thickness of the glass substrate.

15. The display panel as claimed in claim 11, wherein when the display panel is a liquid crystal display panel, the first substrate is a color filter substrate.

16. The display panel as claimed in claim 11, wherein when the display panel is an OLED display panel, the first substrate is a packaged glass substrate.
